(19) United States
(12) Patent Application Publication
(10) Pub. No.: US 2013/0049880 A1
(43) Pub. Date: Feb. 28, 2013

(54) IMPEDANCE MATCHING APPARATUS

(71) Applicants: Kwang Jae Oh, Gyeonggi-do (KR); Joo Yong Kim, Gyeonggi-do (KR)

(72) Inventors: Kwang Jae Oh, Gyeonggi-do (KR); Joo Yong Kim, Gyeonggi-do (KR)

(21) Appl. No.: 13/570,195

(22) Filed: Aug. 8, 2012

(30) Foreign Application Priority Data
Aug. 30, 2011 (KR) 10-2011-0087372

(51) Int. Cl. H03H 7/38

(52) U.S. Cl. 333/32

(57) ABSTRACT

The present invention discloses an impedance matching apparatus. The impedance matching apparatus includes: a multilayer printed circuit board; a signal line including a plurality of signal layers with the same pitch and formed by sequentially arranging the plurality of signal layers on the multilayer printed circuit board; and a ground plane including a plurality of ground layers formed inside the multilayer printed circuit board, wherein the plurality of ground layers are arranged to get closer to a bottom surface of the multilayer printed circuit board from a region corresponding to one side of the signal line to a region corresponding to the other side of the signal line to adjust an impedance value.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2011-0087372, entitled filed Aug. 30, 2011, which is hereby incorporated by reference in its entirety into this application.

### BACKGROUND OF THE INVENTION

1. Field of the Invention

The present invention relates to an impedance matching apparatus, and more particularly, to an impedance matching apparatus capable of adjusting impedance by changing a position of a ground plane.

2. Description of the Related Art

In recent times, according to the development of computer and communication technology, a signal transmission speed becomes important in electronic devices. Accordingly, impedance matching between components and wiring in a printed circuit board or between the printed circuit board and external components is important.

A commonly known impedance matching method is a method of matching impedance by adjusting a width and a pattern form of circuit wiring, a thickness and a permittivity (Er) of an insulating layer, and a thickness of the circuit wiring.

Meanwhile, a multilayer printed circuit board of the current impedance matching apparatus is mainly used for high frequency signal processing.

There are several problems such as propagation delay, transmission line reflection, signal loss, mutual connection due to high connection density, and impedance matching in manufacture of the multilayer printed circuit board for high frequency signal processing.

Further, as the number of layers of the multilayer printed circuit board is increased and a pitch width of a signal line becomes smaller, there is an increasing difficulty in impedance matching. For example, actually, it is difficult to implement the pitch width of the signal line of the multilayer printed circuit board with less than 50 μm.

Like this, there is a limit to match impedance by adjusting the pitch width of the signal line. Therefore, a new impedance matching method, which can match impedance without adjusting a width of circuit wiring, is needed.

### SUMMARY OF THE INVENTION

The present invention has been invented in order to overcome the above-described problems and it is, therefore, an object of the present invention to provide an impedance matching apparatus capable of improving a process yield by determining specific impedance through adjustment of a distance between a signal layer and a ground layer, which are formed in corresponding positions, to implement a line width (pitch width) without any problem of the process yield.

In accordance with an embodiment of the present invention to achieve the object, there is provided an impedance matching apparatus including: a multilayer printed circuit board; a signal line including a plurality of signal layers with the same pitch and formed by sequentially arranging the plurality of signal layers on the multilayer printed circuit board; and a ground plane including a plurality of ground layers formed inside the multilayer printed circuit board, wherein the plurality of ground layers are arranged to get closer to a bottom surface of the multilayer printed circuit board from a region corresponding to one side of the signal line to a region corresponding to the other side of the signal line to adjust an impedance value.

Further, in accordance with an embodiment of the present invention to achieve the object, there is provided an impedance matching apparatus including: a multilayer printed circuit board; a signal line including a plurality of signal layers with the same pitch; and a ground plane including a plurality of ground layers formed inside the multilayer printed circuit board and electrically connected to each other through metal vias, wherein the plurality of ground layers are arranged to get away from the signal line from a region corresponding to one side of the signal line to a region corresponding to the other side of the signal line to adjust an impedance value.

Further, in accordance with an embodiment of the present invention to achieve the object, there is provided an impedance matching apparatus including: a multilayer printed circuit board; a signal line including first and second signal layers formed on the multilayer printed circuit board; and a ground plane including a plurality of ground layers formed inside the multilayer printed circuit board, wherein a first ground layer among the plurality of ground layers, which is formed at one side of the signal line, is arranged to be closer to a bottom surface of the multilayer printed circuit board than a second ground layer among the plurality of ground layers, which is formed at the other side of the signal line, to adjust an impedance value.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a plan view showing an impedance matching apparatus in accordance with a first embodiment of the present invention;

FIG. 2 is a cross-sectional view showing the impedance matching apparatus in accordance with the first embodiment of the present invention;

FIGS. 3a and 3b are views showing an impedance matching apparatus in accordance with a second embodiment of the present invention;

FIGS. 4a and 4b are views showing an impedance matching apparatus in accordance with a third embodiment of the present invention;

FIG. 5 is a plan view showing an impedance matching apparatus in accordance with a fourth embodiment of the present invention;

FIG. 6 is a cross-sectional view showing the impedance matching apparatus in accordance with the fourth embodiment of the present invention;

FIG. 7 is a plan view showing an impedance matching apparatus in accordance with a fifth embodiment of the present invention; and

FIG. 8 is a cross-sectional view showing the impedance matching apparatus in accordance with the fifth embodiment of the present invention.

### DETAILED DESCRIPTION OF THE PREFERABLE EMBODIMENTS

Hereinafter, embodiments of the present invention will be described with reference to the accompanying drawings. The following embodiments are provided as examples, not limiting the present invention.

In describing the present invention, descriptions of well-known components and processing techniques are omitted so as not to unnecessarily obscure the embodiments of the present invention. The following terms are defined in consideration of functions of the present invention and may be changed according to users or operator's intentions or customs. Thus, the terms shall be defined based on the contents described throughout the specification.

The technical spirit of the present invention should be defined by the attached claims, and the following embodiments are merely means for efficiently explaining the technical spirit of the present invention to those skilled in the art.

Hereinafter, an impedance matching apparatus in accordance with embodiments of the present invention will be described with reference to the accompanying drawings.

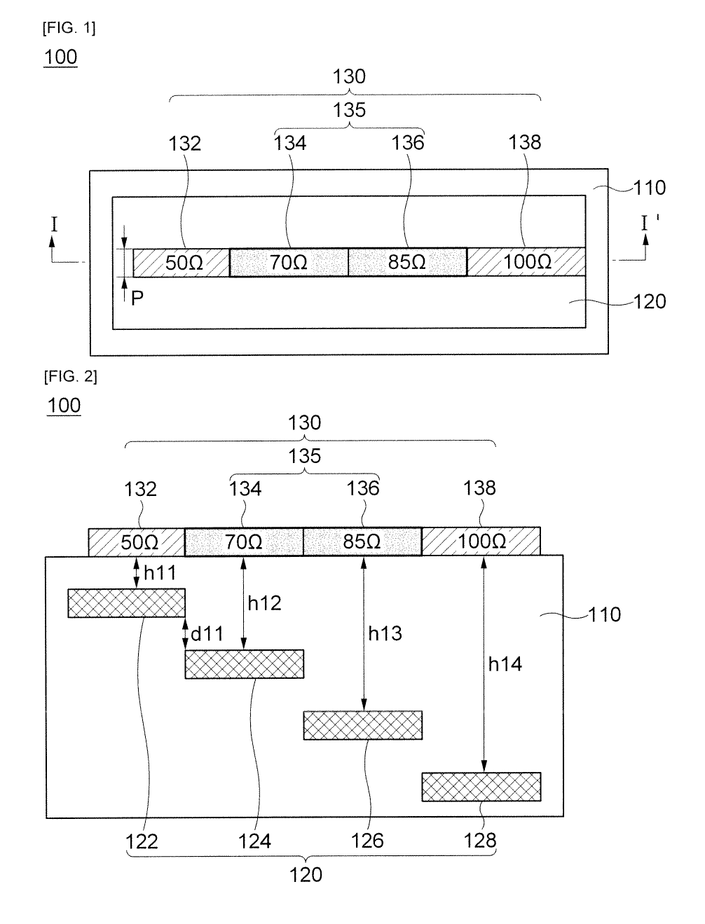

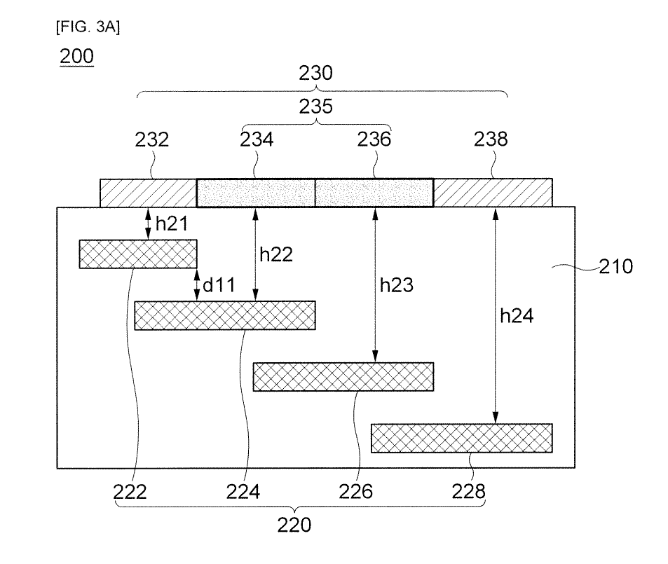

FIG. 1 is a plan view showing an impedance matching apparatus in accordance with a first embodiment of the present invention, and FIG. 2 is a cross-sectional view taken along line I-I′ of FIG. 1.

As shown in FIGS. 1 and 2, an impedance matching apparatus in accordance with a first embodiment includes a ground plane 120 and a signal line 130.

The ground plane 120 is connected to an external ground line to operate as a ground of an antenna and may be made of a conductive metal material, for example, silver (Ag).

This ground plane 120 may consist of a plurality of ground layers 122, 124, 126, and 128. Each of the plurality of ground layers 122, 124, 126, and 128 is formed inside a multilayer printed circuit board 110 and may be formed to have a different height from the adjacent ground layer.

That is, each of the plurality of ground layers 122, 124, 126, and 128 may be formed to get away from the signal line 130 from one side of the signal line 130 to the other side of the signal line 130. That is, the plurality of ground layers 122, 124, 126, and 128 can control an impedance value to be increased by being arranged to get closer to a bottom surface of the multilayer printed circuit board 110 from a region corresponding to one side of the signal line 130 to a region corresponding to the other side of the signal line 130. At this time, the number of the plurality of ground layers 122, 124, 126, and 128 may be the same as the number of divided signal lines 130.

More specifically, as shown in FIG. 2, a first ground layer 122 is arranged in a position corresponding to a low resistance signal layer 132 while being arranged in parallel at a first distance h11 from the low resistance signal layer 132. And a second ground layer 124 is arranged in a position corresponding to a first impedance matching signal layer 134 while being arranged in parallel at a second distance h12, which is greater than the first distance h11, from the first impedance matching signal layer 134. A third ground layer 126 is arranged in a position corresponding to a second impedance matching signal layer 136 while being arranged in parallel at a third distance h13, which is greater than the second distance h12, from the second impedance matching signal layer 136. A fourth ground layer 128 is arranged in a position corresponding to a high resistance signal layer 138 while being arranged in parallel at a fourth distance h14, which is greater than the third distance h13, from the high resistance signal layer 138.

Further, the ground layers 122, 124, 126, and 128 in accordance with the present invention may be formed not to be overlapped with each other while being separated from each other by a first specific distance d11. That is, the respective ground layers 122, 124, 126, and 128 may be formed to have the same height as the respective corresponding signal layers 132, 134, 136, and 138.

Meanwhile, the signal line 130 transceives a predetermined frequency band signal and may be made of a conductive metal material such as silver (Ag).

This signal line 130 is formed on the multilayer printed circuit board 110 in the form of a line with a predetermined pitch (P) interval and, for example, may extend in a longitudinal direction of the multilayer printed circuit board 110.

The signal line 130, as shown in FIGS. 1 and 2, may include the low resistance signal layer 132, the high resistance signal layer, 138, and an impedance matching signal layer 135 formed between the low resistance signal layer 132 and the high resistance signal layer 138 to guide a resistance value to be gradually increased.

Here, the impedance matching signal layer 135 is divided into the first impedance matching signal layer 134 and the second impedance matching signal layer 136. Accordingly, the signal line 130 in accordance with the present invention is divided into total four, and the divided four signal layers 132, 134, 136, and 138 may be formed to have different resistance values.

More specifically, as an example, the low resistance signal layer 132 in accordance with the present invention may be formed to have a resistance of 50 ohm. The first and second impedance matching signal layers 134 and 136 may be sequentially formed to extend from the other side of the low resistance signal layer 132 and may have resistances of 70 ohm and 85 ohm, respectively. And the high resistance signal layer 138 may be formed to extend from the other side of the second impedance matching signal layer 136 and, for example, may have a resistance of 100 ohm.

At this time, the resistance value in the present invention may be determined according to a height difference between the respective signal layers and the respective ground layers 122, 124, 126, and 128 corresponding to the respective signal layers in a parallel direction. Like this, the signal line 130 has a resistance value which is gradually increased from one side to the other side so that impedance matching can be performed.

Like this, the respective ground layers 122, 124, 126, and 128 in accordance with the present invention are separated from the respective corresponding resistance layers 132, 134, 136, and 138 by different distances. Accordingly, the respective resistance layers 132, 134, 136, and 138 have different resistance values determined by the following formulas.

$$Zc = \sqrt{\frac{L}{C}} \qquad [ Formula 1 ]$$

As shown in the formula 1, the resistance value in accordance with the present invention, that is, specific impedance is proportional to a total length L of the signal line and inversely proportional to capacitance C. Due to this, in the present invention, it is possible to adjust a value of the specific impedance by fixing the total length L of the signal line and changing a value of the capacitance C.

$$C = k \frac{permittivity * area}{thickness} \qquad [ Formula 2 ]$$

At this time, it is possible to check that the capacitance C is proportional to permittivity and area and inversely proportional to thickness. Here, the permittivity in accordance with the present invention is determined by a dielectric material formed inside a substrate, and the area represents total area of the substrate. And the thickness in accordance with the present invention represents a distance difference between the signal layer and the ground plane formed corresponding to each other.

Due to this, in the present invention, it is possible to perform impedance matching by fixing values of the permittivity and the area and changing a value of the thickness to change the distance difference between the signal line and the ground plane without changing a pitch width P of the signal line.

Especially, when a line width of the signal layer is fixed, the specific impedance can be determined by the distance between the signal layer and the ground layer formed in corresponding positions. Like this, the specific impedance is determined by the distance between the signal layer and the ground layer formed in corresponding positions without forming the pitch width of the signal layer in a tapered shape in order to adjust the specific impedance so that it is possible to improve a process yield by implementing a line width without any problem of the process yield.

Further, there is no reduction in the process yield due to the fine line width, and it is possible to improve integration of components since there is no need to implement an additional structure on a surface of the substrate.

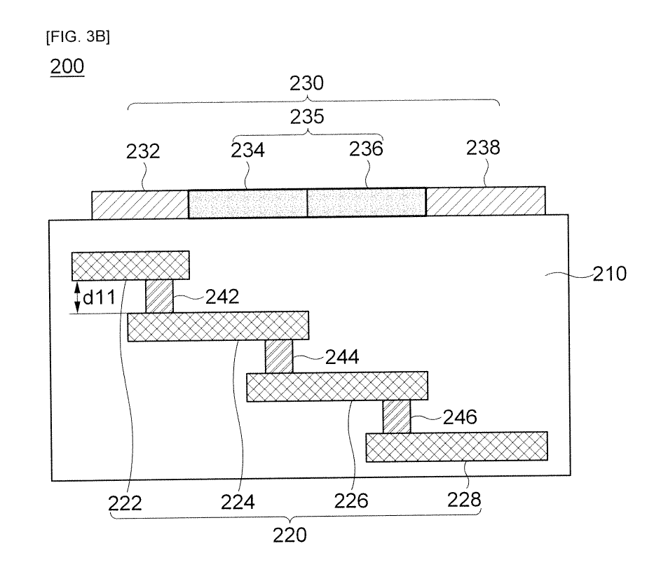

FIG. 3a is a cross-sectional view showing an impedance matching apparatus in accordance with a second embodiment.

As shown in FIG. 3a, an impedance matching apparatus 200 in accordance with a second embodiment of the present invention includes a ground plane 220 and a signal line 230. Here, since the ground plane 220 and the signal line 230 in accordance with the second embodiment of the present invention are the same components as the ground plane 120 and the signal line 130 of the first embodiment of the present invention, repeated description will be omitted.

The ground plane 220 in accordance with the present invention may consist of a plurality of ground layers 222, 224, 226, and 228. Each of the plurality of ground layers 222, 224, 226, and 228 is formed inside a multilayer printed circuit board 210 and may be formed to have a different height from the adjacent ground layer.

Each of the plurality of ground layers 222, 224, 226, and 228 may be formed to get away from the signal line 230 from a position corresponding to one side of the signal line 230 to a position corresponding to the other side of the signal line 230. At this time, the number of the plurality of ground layers 222, 224, 226, and 228 may be the same as the number of divided signal lines 230.

More specifically, a first ground layer 222 is arranged in parallel at a first distance h21 from a low resistance signal layer 232. A second ground layer 224 is arranged in parallel at a second distance h22, which is greater than the first distance h21, from a first impedance matching signal layer 234. A third ground layer 226 is arranged in parallel at a third distance h23, which is greater than the second distance h22, from a second impedance matching signal layer 236. And a fourth ground layer 228 is arranged in parallel at a fourth distance h24, which is greater than the third distance h23, from a high resistance signal layer 238.

Further, the first ground layer 222 is formed to have the same length as the low resistance signal layer 232. However, one side of the second ground layer 224 may extend to a region overlapped with a region in which the first ground layer 222 is formed, and the other side of the second ground layer 224 may extend to a position corresponding to the other side of the first impedance matching signal layer 234. One side of the third ground layer 226 may extend to a region overlapped with a region in which the second ground layer 224 is formed, and the other side of the third ground layer 226 may extend to a position corresponding to the other side of the second impedance matching signal layer 236. Further, one side of the fourth ground layer 228 may extend to a region overlapped with a region in which the third ground layer 226 is formed, and the other side of the fourth ground layer 228 may extend to a position corresponding to the other side of the high resistance signal layer 238.

Meanwhile, as shown in FIG. 3b, the respective ground layers 222, 224, 226, and 228 may be electrically connected to each other through metal vias 242, 244, 246, and 248 formed between the respective ground layers.

These ground layers 222, 224, 226, and 228 in accordance with the present invention may be formed to be separated from each other by a first specific distance d11.

That is, the respective ground layers 222, 224, 226, and 228 in accordance with the present invention are formed to be separated from the respective corresponding resistance layers 232, 234, 236, and 238 by different distances. Accordingly, the respective resistance layers 232, 234, 236, and 238 have different resistance values.

Like this, the impedance matching apparatus 200 in accordance with the present invention determines specific impedance by a distance between the signal layer and the ground layer formed in corresponding positions so that it is possible to improve a process yield by implementing a line width without any problem of the process yield.

Further, there is no reduction in the process yield due to the fine line width, and it is possible to improve integration of components since there is no need to implement an additional structure on a surface of a substrate.

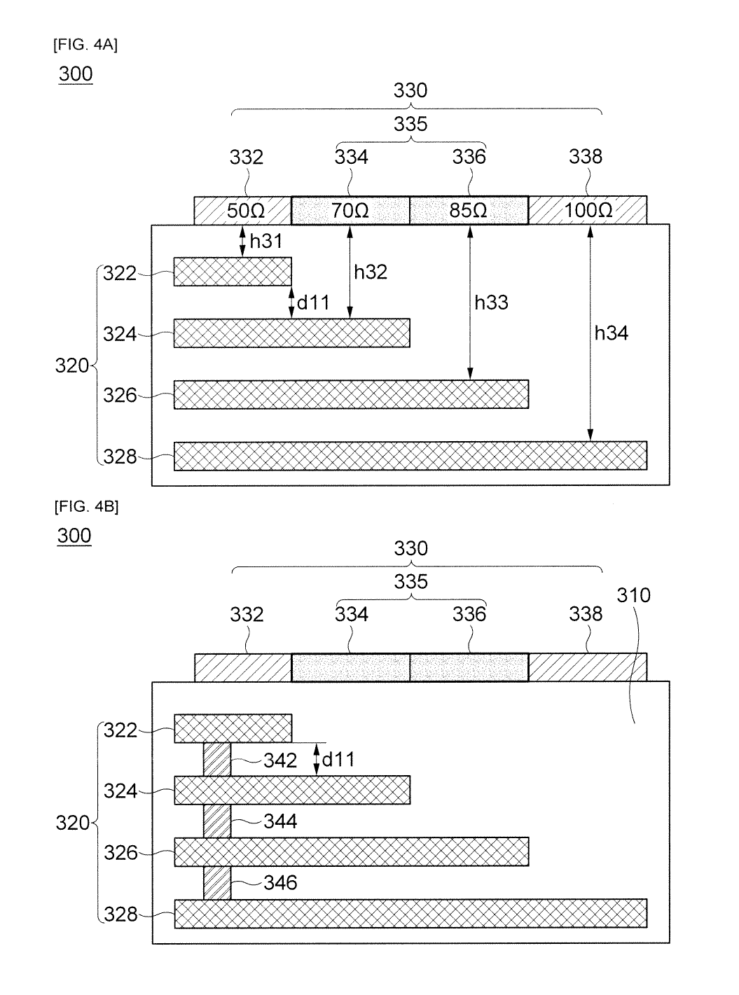

FIG. 4a is a cross-sectional view showing an impedance matching apparatus in accordance with a third embodiment.

As shown in FIG. 4a, an impedance matching apparatus 300 in accordance with a third embodiment of the present invention includes a ground plane 320 and a signal line 330.

Here, the ground plane 320 and the signal line 330 in accordance with the third embodiment of the present invention may be formed to have the same configurations as the ground plane 120 and the signal line 130 of the first embodiment of the present invention.

However, a first ground layer 322 in accordance with the third embodiment of the present invention is formed to have the same length as a low resistance signal layer 332. And one side of each of the second to fourth ground layers 324, 326, and 328 may extend to a region corresponding to one side of the first ground layer 322.

However, the other side of the second ground layer 324 may extend to a position corresponding to the other side of a first impedance matching signal layer 334. The other side of the third ground layer 326 may extend to a position corresponding to the other side of a second impedance matching signal layer 336. Further, the other side of the fourth ground layer 328 may extend to a position corresponding to the other side of a high resistance signal layer 338.

Meanwhile, as in FIG. 4b, the respective ground layers 322, 324, 326, and 328 may be electrically connected to each other through metal vias 342, 344, and 346 formed between the respective ground layers.

These ground layers 322, 324, 326, and 328 in accordance with the present invention may be formed to be separated from each other by a first specific distance d11.

That is, the respective ground layers 322, 324, 326, and 328 in accordance with the present invention are formed to be separated from the respective corresponding resistance layers 332, 334, 336, and 338 by different distances. Accordingly, the respective resistance layers 332, 334, 336, and 338 have different resistance values.

Like this, the impedance matching apparatus 300 in accordance with the present invention determines specific impedance by a distance between the signal layer and the ground layer formed in corresponding positions so that it is possible to improve a process yield by implementing a line width without any problem of the process yield.

Further, there is no reduction in the process yield due to the fine line width, and it is possible to improve integration of components since there is no need to implement an additional structure on a surface of a substrate.

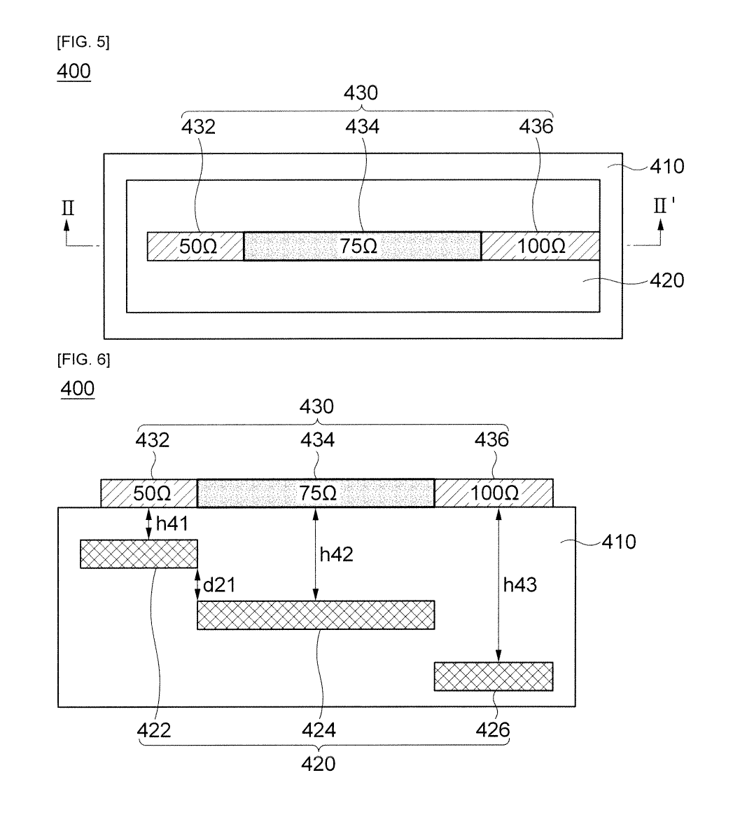

FIG. 5 is a plan view showing an impedance matching apparatus in accordance with a fourth embodiment, and FIG. 6 is a cross-sectional view showing the impedance matching apparatus in accordance with the fourth embodiment.

As shown in FIG. 5, an impedance matching apparatus 400 in accordance with a fourth embodiment of the present invention includes a ground plane 420 and a signal line 430.

Here, the ground plane 420 and the signal line 430 in accordance with the fourth embodiment of the present invention may be formed to have the same configurations as the ground plane 120 and the signal line 130 of the first embodiment of the present invention.

However, as shown in FIGS. 5 and 6, the signal line 430 in accordance with the fourth embodiment of the present invention may include a low resistance signal layer 432, a high resistance signal layer 436, and an impedance matching signal layer 434 formed between the low resistance signal layer 432 and the high resistance signal layer 436 to guide a resistance value to be gradually increased.

Here, the impedance matching signal layer 435 is formed longer than a longitudinal length of each of the low resistance signal layer 432 and the high resistance signal layer 436.

Like this, the signal line 430 in accordance with the present invention is divided into the three signal layers 432, 434, and 436. At this time, the respective signal layers 432, 434, and 436 may be formed to have different resistance values.

More specifically, as an example, the low resistance signal layer 432 in accordance with the present invention is formed to have a resistance of 50 ohm. The impedance matching signal layer 434 extends from the other side of the low resistance signal layer 432 and, for example, may be formed to have a resistance of 75 ohm. And the high resistance signal layer 436 extends from the other side of the impedance matching signal layer 434 and, for example, may be formed to have a resistance of 100 ohm.

As above, as the signal line 430 is divided into the three signal layers 432, 434, and 436, the ground plane in accordance with the present invention also may be formed to have three ground layers 422, 424, and 426.

And the ground layers 422, 424, and 426 may be formed not to be overlapped with each other while being separated from each other by a second specific distance d12, which is greater than the first specific distance d11 shown in FIG. 1. At this time, the respective ground layers 422, 424, and 426 may be formed to have the same length as the respective corresponding signal layers 432, 434, and 436.

Like this, the impedance matching apparatus 400 in accordance with the present invention determines specific impedance by a distance between the signal layer and the ground layer formed in corresponding positions so that it is possible to improve a process yield by implementing a line width without any problem of the process yield.

Further, there is no reduction in the process yield due to the fine line width, and it is possible to improve integration of components since there is no need to implement an additional structure on a surface of a substrate.

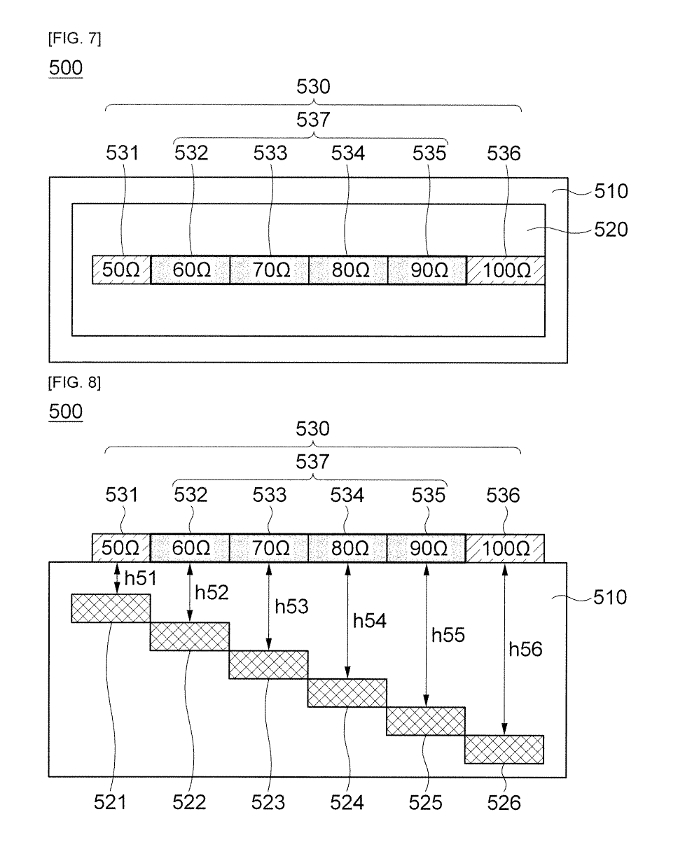

FIG. 7 is a plan view showing an impedance matching apparatus in accordance with a fifth embodiment, and FIG. 8 is a cross-sectional view showing the impedance matching apparatus in accordance with the fifth embodiment.

As shown in FIG. 7, an impedance matching apparatus 500 in accordance with a fifth embodiment of the present invention includes a ground plane 520 and a signal line 530.

Here, the ground plane 520 and the signal line 530 in accordance with the fifth embodiment of the present invention may be formed to have the same configurations as the ground plane 120 and the signal line 130 of the first embodiment of the present invention.

However, as shown in FIGS. 7 and 8, the signal line 530 in accordance with the fifth embodiment of the present invention may include a low resistance signal layer 531, a high resistance signal layer 536, and an impedance matching signal layer 537 formed between the low resistance signal layer 531 and the high resistance signal layer 536 to guide a resistance value to be gradually increased.

Here, the impedance matching signal layer 537 is divided into first to fourth impedance matching signal layers 532, 533, 534, and 535. Accordingly, the signal line 530 in accordance with the present invention is divided into total six, and the divided six signal layers 531, 532, 533, 534, 535, and 536 may be formed to have different resistance values.

More specifically, as an example, the low resistance signal layer 531 is formed to have a resistance of 50 ohm. And the first to fourth impedance matching signal layers 532, 533, 534, and 535 are sequentially formed to extend from the other side of the low resistance signal layer 531 and, for example, may have resistances of 60 ohm, 70 ohm, 80 ohm, and 90 ohm, respectively. And the high resistance signal layer 536 is formed to extend from the other side of the fourth impedance matching signal layer 535 and, for example, may be formed to have a resistance of 100 ohm.

Like this, it is possible to improve signal transmission performance by forming the impedance matching signal layer 537 between the low resistance signal layer 531 and the high resistance signal layer 536 to guide the resistance value to be gradually increased.

As above, as the signal line 530 is divided into the six signal layers 531, 532, 533, 534, 535, and 536, the ground plane according to the present invention also may be formed to have six ground layers 521, 522, 523, 524, 525, and 526.

And the respective ground layers 521, 522, 523, 524, 525, and 526 may formed to have the same length as the respective corresponding signal layers 531, 532, 533, 534, 535, and 536.

Further, each of the ground layers 521, 522, 523, 524, 525, and 526 may be formed to be in contact with the adjacent ground layer without being separated by a specific distance.

Like this, the impedance matching apparatus 500 in accordance with the present invention determines specific impedance by a distance between the signal layer and the ground layer formed in corresponding positions so that it is possible to improve a process yield by implementing a line width without any problem of the process yield.

Further, there is no reduction in the process yield due to the fine line width, and it is possible to improve integration of components since there is no need to implement an additional structure on a surface of a substrate.

An embodiment of the present invention can implement a line width without any problem of a process yield by determining specific impedance by a distance between a signal layer and a ground layer formed in corresponding positions, thereby improving the process yield.

Further, an embodiment of the present invention can improve signal transmission performance by forming an impedance matching signal layer between a low resistance signal layer and a high resistance signal layer to guide a resistance value to be gradually increased.

Accordingly, the impedance matching apparatus does not generate a reduction in the process yield due to the fine line width and can improve integration of components without an additional structure on a surface of a substrate.

What is claimed is:

1. An impedance matching apparatus comprising:
a multilayer printed circuit board;
a signal line comprising a plurality of signal layers and formed by sequentially arranging the plurality of signal layers on the multilayer printed circuit board; and
a ground plane comprising a plurality of ground layers formed inside the multilayer printed circuit board;
wherein the plurality of ground layers are arranged to get closer to a bottom surface of the multilayer printed circuit board from a region corresponding to one side of the signal line to a region corresponding to the other side of the signal line to adjust an impedance value.

2. The impedance matching apparatus according to claim 1, wherein the signal line comprises a low resistance signal layer, a high resistance signal layer, and an impedance matching signal layer formed between the low resistance signal layer and the high resistance signal layer.

3. The impedance matching apparatus according to claim 2, wherein the plurality of ground layers comprise:
a first ground layer arranged in a position corresponding to the low resistance signal layer while being arranged in parallel at a first distance from the low resistance signal layer;
a second ground layer arranged in a position corresponding to the impedance matching signal layer while being arranged in parallel at a second distance, which is greater than the first distance, from the impedance matching signal layer; and
a third ground layer arranged in a position corresponding to the high resistance signal layer while being arranged in parallel at a third distance, which is greater than the second distance, from the high resistance signal layer.

4. The impedance matching apparatus according to claim 3, wherein the first ground layer is formed at the greatest distance from the bottom surface of the multilayer printed circuit board among the plurality of ground layers by being arranged at the first distance, which is the shortest distance from one side of the signal line.

5. The impedance matching apparatus according to claim 3, wherein the third ground layer is formed at the shortest distance from the bottom surface of the multilayer circuit board among the plurality of ground layers by being arranged at the third distance, which is the greatest distance from one side of the signal line.

6. The impedance matching apparatus according to claim 3, wherein the plurality of ground layers are formed to have the same length as the respective corresponding signal layers.

7. The impedance matching apparatus according to claim 3, wherein each of the first to third ground layers are separated from the adjacent ground layer by a specific distance without being overlapped with the adjacent ground layer.

8. The impedance matching apparatus according to claim 3, wherein one side of the second ground layer and one side of the third ground layer are formed to extend to a region corresponding to the first ground layer.

9. The impedance matching apparatus according to claim 8, wherein metal vias are formed between the first to third ground layers so that the first to third ground layers electrically transmit signals to each other.

10. The impedance matching apparatus according to claim 1, wherein the plurality of signal layers are arranged in a row at a predetermined pitch.

11. An impedance matching apparatus comprising:
a multilayer printed circuit board;
a signal line comprising a plurality of signal layers sequentially arranged on the multilayer printed circuit board; and
a ground plane comprising a plurality of ground layers formed inside the multilayer printed circuit board and electrically connected to each other through metal vias;
wherein the plurality of ground layers are arranged to get away from the signal line from a region corresponding to one side of the signal line to a region corresponding to the other side of the signal line to adjust an impedance value.

12. The impedance matching apparatus according to claim 11, wherein the signal line comprises a low resistance signal layer, a high resistance signal layer, and an impedance matching signal layer formed between the low resistance signal layer and the high resistance signal layer.

13. The impedance matching apparatus according to claim 12, wherein the plurality of ground layers comprise:
a first ground layer arranged in a position corresponding to the low resistance signal layer while being arranged in parallel at a first distance from the low resistance signal layer;
a second ground layer arranged in a position corresponding to the low resistance signal layer and the impedance matching signal layer while being arranged in parallel at a second distance, which is greater than the first distance, from the low resistance signal layer and the impedance matching signal layer; and
a third ground layer arranged in a position corresponding to the impedance matching signal layer and the high resistance signal layer while being arranged in parallel at a third distance, which is greater than the second distance, from the impedance matching signal layer and the high resistance signal layer.

14. An impedance matching apparatus comprising:
a multilayer printed circuit board;
a signal line comprising first and second signal layers formed on the multilayer printed circuit board; and
a ground plane comprising a plurality of ground layers formed inside the multilayer printed circuit board,
wherein a first ground layer among the plurality of ground layers, which is formed at one side of the signal line, is arranged to be closer to a bottom surface of the multilayer printed circuit board than a second ground layer among the plurality of ground layers, which is formed at the other side of the signal line, to adjust an impedance value.
